(19) United States
(12) Patent Application Publication
(10) Pub. No.: US 2013/0334495 A1
(43) Pub. Date: Dec. 19, 2013

(54) SUPERLATTICE STRUCTURE, SEMICONDUCTOR DEVICE INCLUDING THE SAME, AND METHOD OF MANUFACTURING THE SEMICONDUCTOR DEVICE

(71) Applicants: Dae-ho LIM, Suwon-si (KR); Joo-sung KIM, Seongnam-si (KR); Jae-kyun KIM, Hwaseong-si (KR); Young-jo TAK, Hwaseong-si (KR)

(72) Inventors: Dae-ho LIM, Suwon-si (KR); Joo-sung KIM, Seongnam-si (KR); Jae-kyun KIM, Hwaseong-si (KR); Young-jo TAK, Hwaseong-si (KR)

(21) Appl. No.: 13/837,992

(22) Filed: Mar. 15, 2013

(30) Foreign Application Priority Data
Jun. 15, 2012 (KR) 10-2012-0064588

(51) Int. Cl. H01L 29/12; H01L 21/02

(52) U.S. Cl. CPC H01L 29/122; H01L 21/0254
USPC 257/15; 438/478

(57) ABSTRACT

A superlattice structure, and a semiconductor device including the same, include a plurality of pairs of layers are in a pattern repeated at least two times, in which a first layer and a second layer constitute a pair, the first layer is formed of AlₓIn_{y}Ga_{1-x-y}N (where 0≦x and y≦1), the second layer is formed of AlₐIn_{b}Ga_{1-a-b}N (where 0≦a, b≦1 and x≠a), the first and second layers have the same thickness, and a total thickness of each of the plurality of pairs of layers is different than each other.

### CROSS-REFERENCE TO RELATED APPLICATIONS

This application claims the benefit of priority under 35 U.S.C. §119 from Korean Patent Application No. 10-2012-0064588, filed on June 15, 2012, in the Korean Intellectual Property Office, the disclosure of which is incorporated herein by reference in its entirety.

### BACKGROUND

1. Field

The present disclosure relates to a superlattice structure for reducing cracks in a nitride-based semiconductor thin film, a semiconductor device including the superlattice structure, and a method of manufacturing the semiconductor device.

2. Description of the Related Art

Many nitride-based semiconductor devices use a sapphire substrate. However, a sapphire substrate is expensive, is too hard to manufacture chips, and has a low electric conductivity. Furthermore, a sapphire substrate may not be easily manufactured with a large size due to its warpage at high temperatures (e.g., during epitaxial growth) and due to its low thermal conductivity. In order to prevent the above problems, nitride-based semiconductor devices using a silicon (Si) substrate instead of a sapphire substrate have been developed. Because a Si substrate has a higher thermal conductivity than a sapphire substrate, the Si substrate is not warped greatly at a high temperature for growing a nitride thin film, thereby making it possible to grow a large thin film on the Si substrate. However, when a nitride thin film is grown on a Si substrate, a dislocation density may be increased due to a mismatch in lattice constants between the Si substrate and the nitride thin film, and cracks may occur due to a mismatch in thermal expansion coefficients between the Si substrate and the nitride thin film. Accordingly, many methods for reducing dislocation densities and preventing cracks have been studied. In order to use a Si substrate, there is a need for a method of preventing cracks due to tensile stress generated by a thermal expansion difference.

### SUMMARY

Provided is a superlattice structure for reducing cracks in a nitride-based semiconductor thin film.

Provided is a semiconductor device for reducing cracks in a nitride-based semiconductor thin film grown on a substrate.

According to example embodiments, a superlattice structure includes a plurality of pairs of layers in a pattern repeated at least two times, wherein a first layer and a second layer of the plurality of pairs of layers constitute a pair, the first layer is formed of AlₓIn_{y}Ga_{1-x-y}N (where 0≦x and y≦1), the second layer is formed of AlₐIn_{b}Ga_{1-a-b}N (where 0≦a, b≦1 and x≠a), and the first layer has a thickness equal to a thickness of the second layer. A total thickness of each of the plurality of pairs of layers is different than each other.

The total thickness of each of the plurality of pairs of layers may increase in a direction in which the plurality of pairs of layers are stacked. The total thickness of each of the plurality of pairs of layers may increase linearly in the direction in which the plurality of pairs of layers are stacked.

A composition ratio of aluminum (Al) in the first layer may be greater than a composition ratio of Al in the second layer. A composition ratio of Al in each layer in the plurality of pairs of layers may decrease, or an average composition ratio of Al in each of the plurality of pairs of layers may decrease, in a direction in which the plurality of pairs of layers are stacked.

A composition ratio of Al in each layer of the plurality of pairs of layers may decrease linearly, or an average composition ratio of Al in each of the plurality of pairs of layers may decrease linearly, in the direction in which the plurality of pairs of layers are stacked.

A composition ratio of Al in the first layer may be greater than a composition ratio of Al in the second layer. The plurality of pairs of layers may be repeatedly stacked having a same composition ratio of Al in a repeating pattern.

Each of the first layer and the second layer may have a thickness from about 0.1 nm to about 20 nm. Each of the first layer and the second layer may have a thickness from about 0.1 nm to about 10 nm.

Each of the plurality of pairs of layers may further include a third layer formed of AlₚIn_{q}Ga_{1-p-q}N (where 0≦p, q≦1 and x≠a≠p). The third layer may have a thickness equal to the thickness of the second layer.

The superlattice structure may be repeatedly stacked at least two times. An average composition ratio of Al in the superlattice structure may decrease in a direction in which the superlattice structure is repeatedly stacked.

According to other example embodiments, a semiconductor device includes a seed growth layer on a substrate, a superlattice structure on the seed growth layer, and a nitride stack structure on the superlattice structure. The superlattice structure may include a plurality of pairs of layers in a pattern repeated at least two times, wherein a first layer and a second layer of the plurality of pairs of layers constitute a pair, the first layer is formed of AlₓIn_{y}Ga_{1-x-y}N (where 0≦x and y≦1) and the second layer is formed of AlₐIn_{b}Ga_{1-a-b}N (where 0≦a, b≦1 and x≠a), the first layer has a thickness equal to a thickness of the second layer, and a total thickness of each of the plurality of pairs of layers is different than each other.

A total thickness of each of the plurality of pairs of layers may increase in a direction in which the plurality of pairs of layers are stacked. The total thickness of each of the plurality of pairs of layers may increase linearly in the direction in which the plurality of pairs of layers are stacked.

A composition ratio of aluminum (Al) in the first layer may be greater than a composition ratio of Al in the second layer. A composition ratio of Al in each layer in the plurality of pairs of layers may decrease, or an average composition ratio of Al in each of the plurality of pairs of layers may decrease, in a direction in which the plurality of pairs of layers are stacked.

A composition ratio of Al in each layer of the plurality of pairs of layers may decrease linearly, or an average composition ratio of Al in each of the plurality of pairs of layers may decrease linearly, in a direction in which the plurality of pairs of layers are stacked.

A composition ratio of Al in the first layer may be greater than a composition ratio of Al in the second layer. The plurality of pairs of layers may be repeatedly stacked having a same composition ratio of Al in a repeating pattern.

Each of the first layer and the second layer may have a thickness from about 0.1 nm to about 20 nm. Each of the first layer and the second layer may have a thickness from about 0.1 nm to about 10 nm.

Each of the plurality of pairs of layers may further include a third layer formed of AlₚIn_{q}Ga_{1-p-q}N (where 0≦p, q≦1 and x≠a≠p), and the third layer may have a thickness equal to the thickness of the second layer.

The superlattice structure may be repeatedly stacked at least two times.

An average composition ratio of Al in the superlattice structure may decrease in a direction in which the superlattice structure is repeatedly stacked.

The substrate may contain silicon (Si).

The seed growth layer may be formed of Al_{c}In_{d}Ga_{1-c-d}N (wherein 0≦c, d≦1).

The semiconductor device may further include at least one nitride interlayer selected from a SiN interlayer and an AlGaN interlayer in a nitride semiconductor layer in the nitride stack or over the superlattice structure.

According to further example embodiments, a superlattice structure includes a plurality of pairs of layers in a pattern repeated at least two times, wherein a first layer and a second layer of the plurality of pairs of layers constitute a first pair, and a third layer and a fourth layer of the plurality of pairs of layers constitute a second pair. Either a composition ratio of aluminum (Al) in the first layer is greater than a composition ratio of Al in the second layer or a composition ratio of Al in the first pair is greater than a composition ratio of Al in the second pair. The first layer has a thickness equal to a thickness of the second layer, and the third layer has a thickness equal to a thickness of the fourth layer. A total thickness of each of the plurality of pairs of layers is different than each other.

The second layer may be over the first layer, and the fourth layer may be over the third layer. The second pair may be over the first pair.

A total thickness of the first pair may be less than a total thickness of the second pair.

According to further example embodiments, a method of manufacturing a semiconductor device includes stacking on a substrate a first layer formed on AlₓIn_{y}Ga_{1-x-y}N (where 0≦x and y≦1); stacking on the first layer a second layer formed of AlₐIn_{b}Ga_{1-a-b}N (where 0≦a, b≦1 and x≠a); alternately stacking the first layer and the second layer on the second layer at least one time; and stacking a nitride stack structure on the stacked layer, wherein a plurality of pairs of layers each pair including the first layer and the second layer are stacked, the first layer has a thickness equal to a thickness of the second layer, and a total thickness of each of the plurality of pairs of layers is different than each other.

### BRIEF DESCRIPTION OF THE DRAWINGS

Example embodiments will be more clearly understood from the following detailed description taken in conjunction with the accompanying drawings. FIGS. 1-7 represent non-limiting, example embodiments as described herein.

FIG. 1 is a schematic cross-sectional view of a superlattice structure according to example embodiments;

FIG. 2 is a cross-sectional view of a superlattice structure according to other example embodiments;

FIG. 3 is a cross-sectional view of a superlattice structure according to yet other example embodiments;

FIG. 4 is a cross-sectional view of a superlattice structure according to still other example embodiments;

FIG. 5 is a cross-sectional view of a superlattice structure including a multilayered structure according to further example embodiments;

FIG. 6 is a schematic cross-sectional view of a semiconductor device according to yet further example embodiments;

FIG. 7 is a schematic cross-sectional view of a semiconductor device according to still further example embodiments; and

FIG. 8 is a cross-sectional view of a semiconductor device manufactured by using a method of manufacturing the semiconductor device according to example embodiments.

### DETAILED DESCRIPTION

Various example embodiments will now be described more fully with reference to the accompanying drawings in which some example embodiments are shown. However, specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a superlattice structure, a semiconductor device including the superlattice structure, and a method of manufacturing the semiconductor device will be described with regard to example embodiments with reference to the attached drawings. Hereinafter, it will also be understood that when a layer is referred to as being on another layer or substrate, it can be directly on the other layer or substrate, or intervening layers may also be present. Expressions such as “at least one of,” when preceding a list of elements, modify the entire list of elements and do not modify the individual elements of the list.

The present disclosure relates to a superlattice structure for reducing cracks in a nitride-based semiconductor thin film, and a semiconductor device including the superlattice structure.

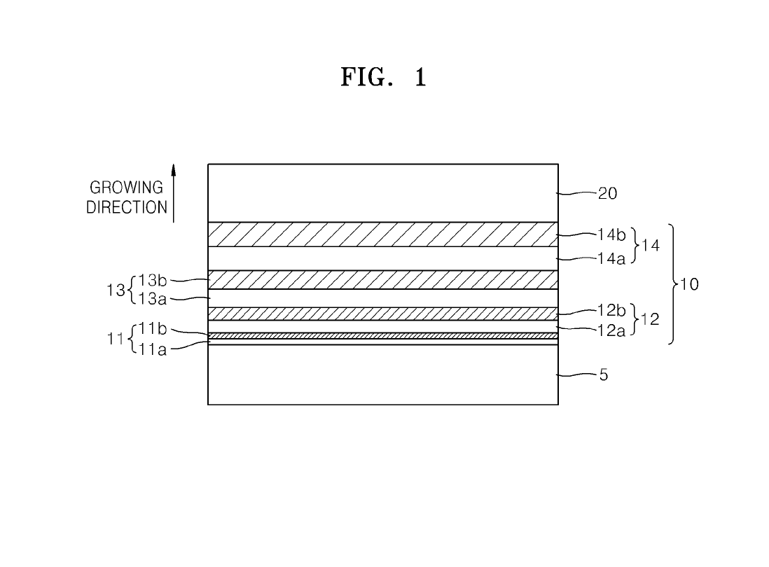

FIG. 1 is a schematic cross-sectional view of a superlattice structure according to example embodiments.

In FIG. 1, a superlattice structure 10 may be grown by alternately growing different material layers to maintain superlattice constants of the material layers. The superlattice structure 10 may include a plurality of pairs of layers that are repeatedly stacked at least two times, and in this case, upper and lower layers constituting a pair are formed of different materials. A pair may be a minimum stack unit which layers are repeatedly stacked based on a thickness of each layer. Two layers constituting the pair may have the same thickness and the plurality of pairs may have different total thicknesses. For example, the lower layer may be formed of AlₓIn_{y}Ga_{1-x-y}N (0≦x, y≦1) and the upper layer may be formed of AlₐIn_{b}Ga_{1-a-b}N (0≦a, b≦1, and x≠a).

Referring to FIG. 1, the superlattice structure 10 may include a first pair 11 including a first layer 11a and a second layer 11b, a second pair 12 including a third layer 12a and a fourth layer 12b, a third pair 13 including a fifth layer 13a and a sixth layer 13b, and a fourth pair 14 including a seventh layer 14a and an eighth layer 14b. The first layer 11a and the second layer 11b may have the same thickness, the third layer 12a and the fourth layer 12b may have the same thickness, the fifth layer 13a and the sixth layer 13b may have the same thickness, the seventh layer 14a and the eighth layer 14b may have the same thickness. In addition, a total thickness of the first pair 11, a total thickness of the second pair 12, a total thickness of the third pair 13, a total thickness of the fourth pair 14 may be different. For example, a total thickness of each pair may increase in a direction in which each layer is grown. For example, a total thickness of each pair may linearly increase.

Compositions of layers constituting a pair may be the same, or may be different. Composition ratios of aluminum (Al) of layers constituting each pair may be the same, or may be different. When composition ratios of Al of layers constituting each pair are different, an average composition ratio of Al of each pair may decrease in a direction in which each layer of the superlattice structure 10 is grown. For example, an average composition ratio of Al of each pair may linearly decrease. In addition, a composition ratio of Al of the lower layer of each pair may be greater than a composition ratio of Al of the upper layer of each pair.

In addition, compositions of layers included in the superlattice structure 10 may be different. Alternatively, layers constituting each pair in the superlattice structure 10 may be different, and composition ratios of pairs of layers may be the same. Layers constituting a pair may each have a thickness of about 0.1 to about 20 nm. Alternatively, layers constituting a pair may each have a thickness of about 0.1 to about 10 nm.

A seed growth layer 5 may be disposed below the superlattice structure 10. The seed growth layer 5 may be formed of Al_{c}In_{d}Ga_{(1-c-d)}N (0≦c, d≦1). The seed growth layer 5 may be formed of, for example, AlN. In addition, at least one nitride semiconductor layer 20 may be disposed on the superlattice structure 10. The nitride semiconductor layer 20 may include, for example, gallium (Ga).

Three layers or more may constitute a pair. Layers constituting each pair may have the same thickness, and may have different compositions. In addition, pairs of layers may have different compositions. According to example embodiments, a pair may be a minimum stack unit based on a thickness of each layer. Compositions of layers of each pair may be the same, or may be different. That is, compositions of layers constituting each pair may be configured in various combinations. For example, a pair of layers may include a first layer formed of AlₓIn_{y}Ga_{1-x-y}N (0≦x, y≦1), a second layer formed of AlₐIn_{b}Ga_{1-a-b}N (0≦a, b≦1 and x≠a), and a third layer formed of AlₚIn_{q}Ga_{1-p-q}N (0≦p, q≦1 and x≠a≠p).

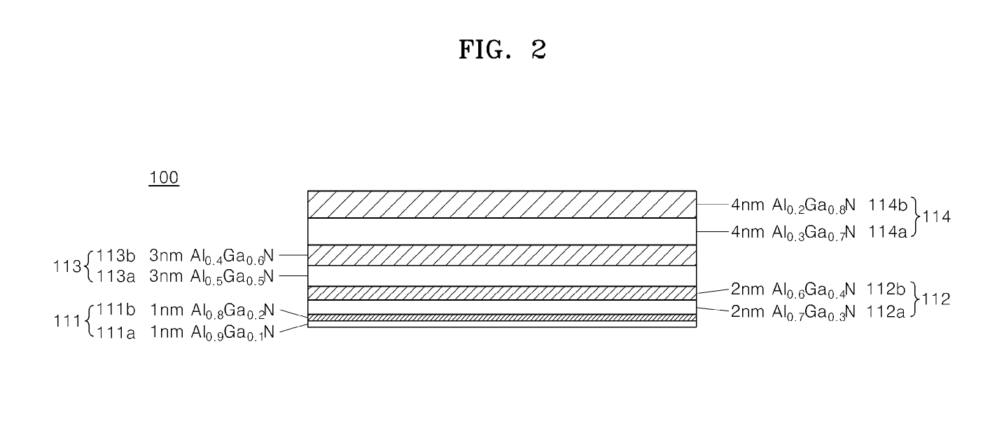

FIG. 2 is a cross-sectional view of a superlattice structure according to other example embodiments.

Referring to FIG. 2, a superlattice structure 100 may include a first pair 111 including a first layer 111a having a thickness of 1 nm and a second layer 111b having a thickness of 1 nm, a second pair 112 including a third layer 112a having a thickness of 2 nm and a fourth layer 112b having a thickness of 2 nm, a third pair 113 including a fifth layer 113a having a thickness of 3 nm and a sixth layer 113b having a thickness of 3 nm, and a fourth pair 114 including a seventh layer 114a having a thickness of 4 nm and an eighth layer 114b having a thickness of 4 nm. The first layer 111a may be formed of Al_{0.9}Ga_{0.1}N and the second layer 111b may be formed of Al_{0.8}Ga_{0.2}N. The third layer 112a may be formed of Al_{0.7}Ga_{0.3}N and the fourth layer 112b may be formed of Al_{0.6}Ga_{0.4}N. The fifth layer 113a may be formed of Al_{0.5}Ga_{0.5}N and the sixth layer 113b may be formed of Al_{0.4}Ga_{0.6}N. The seventh layer 114a may be formed of Al_{0.3}Ga_{0.7}N and the eighth layer 114b may be formed of Al_{0.2}Ga_{0.8}N.

In the superlattice structure 100, two layers constituting a pair may have the same thickness, pairs of layers may have different total thicknesses, and layers of the superlattice structure 100 may have different compositions. In addition, a composition ratio of Al of each layer may decrease upward. For example, a composition ratio of Al of each layer may linearly decrease. In this case, an upward direction may be a direction in which layers included in the superlattice structure 100 are grown. Unlike in FIG. 2, example embodiments may be embodied in various forms, and for example, average composition ratios of Al of each pair of the superlattice structure 100 may decrease in a direction in which layers of the superlattice structure 100 are grown.

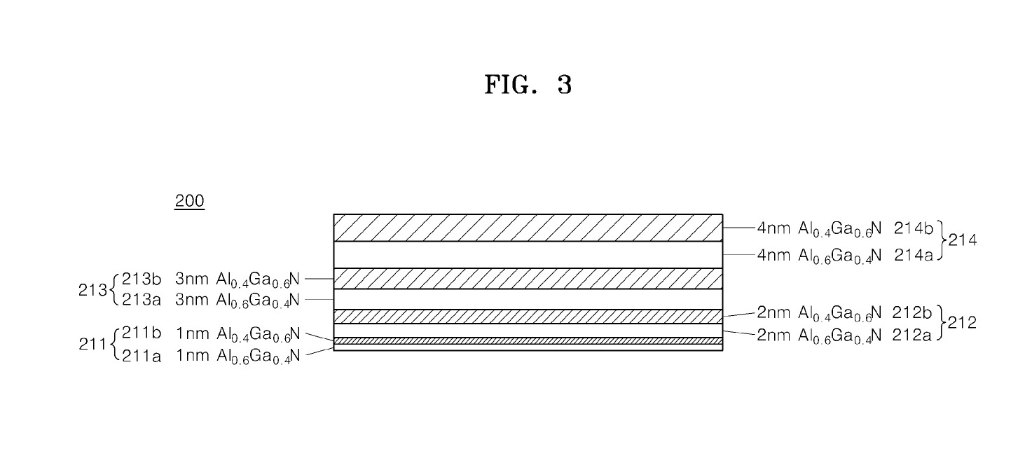

FIG. 3 is a cross-sectional view of a superlattice structure according to yet other example embodiments.

Referring to FIG. 3, a superlattice structure 200 may include a first pair 211 including a first layer 211a having a thickness of 1 nm and a second layer 211b having a thickness of 1 nm, a second pair 212 including a third layer 212a having a thickness of 2 nm and a fourth layer 212b having a thickness of 2 nm, a third pair 213 including a fifth layer 213a having a thickness of 3 nm and a sixth layer 213b having a thickness of 3 nm, and a fourth pair 214 including a seventh layer 214a having a thickness of 4 nm and an eighth layer 214b having a thickness of 4 nm. The first layer 211a may be formed of Al_{0.6}Ga_{0.4}N and the second layer 211b may be formed of Al_{0.4}Ga_{0.6}N. The third layer 212a may be formed of Al_{0.6}Ga_{0.4}N and the fourth layer 212b may be formed of Al_{0.4}Ga_{0.6}N. The fifth layer 213a may be formed of Al_{0.6}Ga_{0.4}N and the sixth layer 213b may be formed of Al_{0.6}Ga_{0.4}N. The seventh layer 214a may be formed of Al_{0.6}Ga_{0.4}N and the eighth layer 214b may be formed of Al_{0.4}Ga_{0.6}N. In the superlattice structure 200, total thicknesses of pairs of layers may be different, and compositions of layers constituting each pair may be the same.

Layers constituting each pair may be formed of, for example, AlₓIn_{y}Ga_{1-x-y}N (0≦x, y≦1)/AlₐIn_{b}Ga_{1-a-b}N (0≦a, b≦1 and x≠a). Thus far, the case where each of the layers of a pair includes Al has been described. However, example embodiments are not limited thereto. For example, each pair may include AlN/GaN. Alternatively, each pair may include AlₓGa₁₋ₓN/AlₐGa₁₋ₐN (0<x, a≦1 and x≠a). Layers constituting each pair may each have a thickness of about 0.1 to about 20 nm. Alternatively, layers constituting each pair may have a thickness of about 0.1 nm to about 10 nm.

FIG. 4 is a cross-sectional view of a superlattice structure according still other example embodiments.

In FIG. 4, a superlattice structure 300 may be a multilayered superlattice structure obtained by stacking a plurality of superlattice units.

Each of the superlattice units may include a plurality of pairs of layers that are repeatedly stacked at least two times, and in this case, first and second layers constituting a pair are formed of different materials. A pair may be a minimum stack unit, and in this case, thicknesses of layers may vary periodically. That is, the first and second layers may have the same thickness and total thicknesses of the first and second layers of layers may be different. That is, a total thickness of each pair may increase in a direction in which layers of each of the superlattice units are grown. The first layer may be formed of AlₓIn_{y}Ga_{1-x-y}N (0≦x, y≦1) and the second layer may be formed of AlₐIn_{b}Ga_{1-a-b}N (0≦a, b≦a1, and x≠a). Each of the superlattice units may include a stack structure having a minimum period, in which a total thickness of each pair varies in a direction in which layers of each of the superlattice units are grown. For example, each of the superlattice units may include a structure including layers of which a total thickness increases in a direction in which layers are grown.

Referring to FIG. 4, the superlattice structure 300 may include a first superlattice unit 310, a second superlattice unit 320, and a third superlattice unit 330.

The first superlattice unit 310 may include a first pair 311 including a first layer 311a and a second layer 311b, a second pair 312 including a third layer 312a and a fourth layer 312b, a third pair 313 including a fifth layer 313a and a sixth layer 313b, and a fourth pair 314 including a seventh layer 314a and an eighth layer 314b. The first layer 311a and the second layer 311b may have the same thickness, the third layer 312a and the fourth layer 312b may have the same thickness, the fifth layer 313a and the sixth layer 313b may have the same thickness, and the seventh layer 314a and the eighth layer 314b may have the same thickness. In addition, a total thickness of the first pair 311, a total thickness of the second pair 312, a total thickness of the third pair 313, and a total thickness of the fourth pair 314 may be different. For example, a total thickness of each pair may increase in a direction in which layers are grown. Each pair of layers of the first superlattice unit 310 may include, for example, an AlₓIn_{y}Ga_{1-x-y}N (0≦x, y≦1)/AlₐIn_{b}Ga_{1-a-b}N (0≦a, b≦1 and x≠a) layer. In addition, for example, in each of the superlattice units, an average composition ratio of Al of each pair may not be changed, or may decrease in a direction in which layers are grown. Alternatively, layers constituting a pair in the first superlattice unit 310 may be formed of AlN/GaN. In addition, layers constituting a pair may be configured in various combinations.

The second superlattice unit 320 may include a stack structure having a period at which a total thickness of each pair of layers increases in a direction in which layers are grown. For example, the second superlattice unit 320 may include a fifth pair 321 including a ninth layer 321a and a tenth layer 321b, a sixth pair 322 including an eleventh layer 322a and a twelfth layer 322b, a seventh pair 323 including a thirteenth layer 323a and a fourth layer 323b, and a eighth pair 324 including a fifteenth layer 324a and a sixteenth layer 324b. The ninth layer 321a and the tenth layer 321b may have the same thickness, the eleventh layer 322a and the twelfth layer 322b may have the same thickness, the thirteenth layer 323a and the fourth layer 323b may have the same thickness, and the fifteenth layer 324a and the sixteenth layer 324b may have the same thickness. In addition, a total thickness of the fifth pair 321, a total thickness of the sixth pair 322, a total thickness of seventh pair 323, and a total thickness of the eighth pair 324 may be different. For example, a total thickness of each pair may increase in a direction in which layers are grown.

Each pair of layers of the second superlattice unit 320 may include, for example, an AlₓIn_{y}Ga_{1-x-y}N (0≦x, y≦1)/AlₐIn_{b}Ga_{1-a-b}N (0≦a, b≦1 and x≠a) layer, and average composition ratios of Al of pairs of layers may be the same, or an average composition ratio of Al may decrease in a direction in which layers are grown. Alternatively, layers constituting a pair of layers of the second superlattice unit 320 may be formed of AlN/GaN. In addition, layers constituting a pair may be configured in various combinations.

The third superlattice unit 330 may include a stack structure having a period at which a total thickness of each pair of layers increases in a direction in which layers are grown. For example, the third superlattice unit 330 may include a ninth pair 331 including a seventeenth layer 331a and an eighteenth layer 331b, a tenth pair 332 including a nineteenth layer 332a and a twentieth layer 332b, an eleventh pair 333 including a twenty first layer 333a and a twenty second layer 333b, and a twelfth pair 334 including a twenty third layer 334a and a twenty fourth layer 334b. The seventh layer 331a and the eighth layer 331b may have the same thickness, the ninth layer 332a and the twentieth layer 332b may have the same thickness, the twenty first layer 333a and the twenty second layer 333b may have the same thickness, and the twenty third layer 334a and the twenty fourth layer 334b may have the same thickness. In addition, a total thickness of the ninth pair 331, a total thickness of the tenth pair 332, a total thickness of the eleventh pair 333, and a total thickness of the twelfth pair 334 may be different. For example, a total thickness of each pair of layers may increase in a direction in which layers are grown.

Each pair of layers of the third superlattice unit 330 may include, for example, an AlₓIn_{y}Ga_{1-x-y}N (0≦x, y≦1)/AlₐIn_{b}Ga_{1-a-b}N (0≦a, b≦1 and x≠a) layer, and average composition ratios of Al of pairs of layers may be the same, or an average composition ratio of Al may decrease in a direction in which layers are grown. Alternatively, layers constituting a pair of layers of the third superlattice unit 330 may be formed of AlN/GaN. In addition, layers constituting a pair may be configured in various combinations.

In each of the first superlattice unit 310, the second superlattice unit 320, and the third superlattice unit 330, layers constituting each pair may each have a thickness of about 0.1 to about 20 nm, or alternatively, may each have a thickness in the range of about 0.1 to about 10 nm.

In each of the first superlattice unit 310, the second superlattice unit 320, and the third superlattice unit 330, layers may have the same thickness and composition. Alternatively, in each of the first superlattice unit 310, the second superlattice unit 320, and the third superlattice unit 330, at least one of the thicknesses and compositions of layers may be different. FIG. 4 shows the case where two layers constitute a pair. However, three layers or more may constitute a pair.

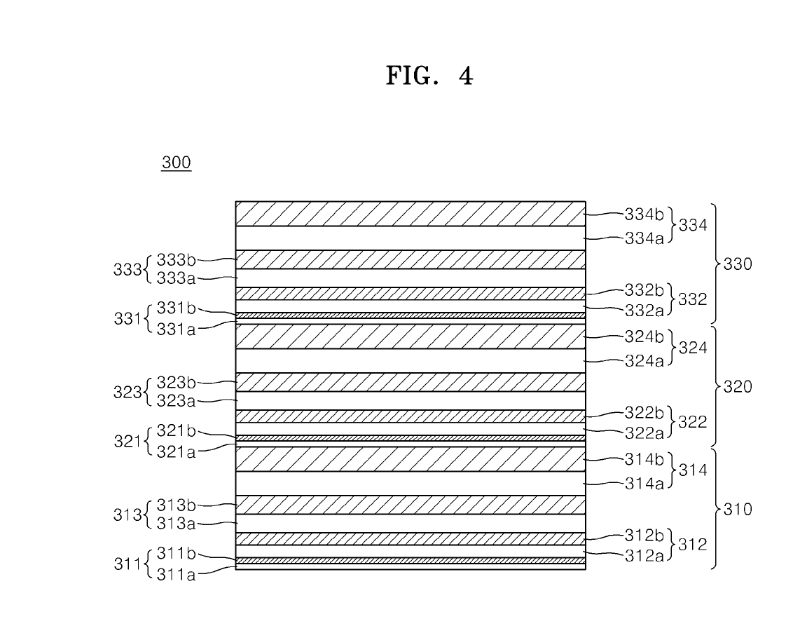

FIG. 5 is a cross-sectional view of a superlattice structure including a multilayered structure, according to further example embodiments.

Referring to FIG. 5, a superlattice structure 400 may include, for example, a first superlattice unit 410, a second superlattice unit 420, and a third superlattice unit 430.

The first superlattice unit 410 may include a first pair including an Al_{0.85}Ga_{0.15}N layer having a thickness of 1 nm and an Al_{0.65}Ga_{0.35}N layer having a thickness of 1 nm, a second pair including an Al_{0.85}Ga_{0.15}N layer having a thickness of 2 nm and an Al_{0.65}Ga_{0.35}N layer having a thickness of 2 nm, a third pair including an Al_{0.85}Ga_{0.15}N having a thickness of 3 nm and an Al_{0.65}Ga_{0.35}N layer having a thickness of 3 nm, and a fourth pair including an Al_{0.85}Ga_{0.15}N layer having a thickness of 4 nm and an Al_{0.65}Ga_{0.35}N layer having a thickness of 4 nm.

The second superlattice unit 420 may include a first pair including an Al_{0.6}Ga_{0.4}N layer having a thickness of 1 nm and an Al_{0.6}Ga_{0.4}N layer having a thickness of 1 nm, a second pair including an Al_{0.6}Ga_{0.4}N layer having a thickness of 2 nm and an Al_{0.6}Ga_{0.4}N layer having a thickness of 2 nm, a third pair including an Al_{0.6}Ga_{0.4}N layer having a thickness of 3 nm and an Al_{0.6}Ga_{0.4}N layer having a thickness of 3 nm, and a fourth pair including an Al_{0.6}Ga_{0.4}N layer having a thickness of 4 nm and an Al_{0.6}Ga_{0.4}N layer having a thickness of 4 nm.

The third superlattice unit 430 may include a first pair including an Al_{0.35}Ga_{0.65}N layer having a thickness of 1 nm and an Al_{0.15}Ga_{0.85}N layer having a thickness of 1 nm, a second pair including an Al_{0.35}Ga_{0.65}N layer having a thickness of 2 nm and an Al_{0.15}Ga_{0.85}N layer having a thickness of 1 nm, a third pair including an Al_{0.35}Ga_{0.65}N layer having a thickness of 3 nm and an Al_{0.15}Ga_{0.85}N layer having a thickness of 4 nm, and a fourth pair including an Al_{0.35}Ga_{0.65}N layer having a thickness of 4 nm and an Al_{0.15}Ga_{0.85}N layer having a thickness of 4 nm.

FIG. 5 shows the case where changes in thickness of each pair are the same, and compositions of pairs are different. However, the case of FIG. 5 is just an example. That is, at least one of changes in thickness of each pair and compositions of pairs may be changed. Alternatively, a plurality of superlattice units may be configured in such a way that changes in thickness of each pair and compositions of pairs may be the same.

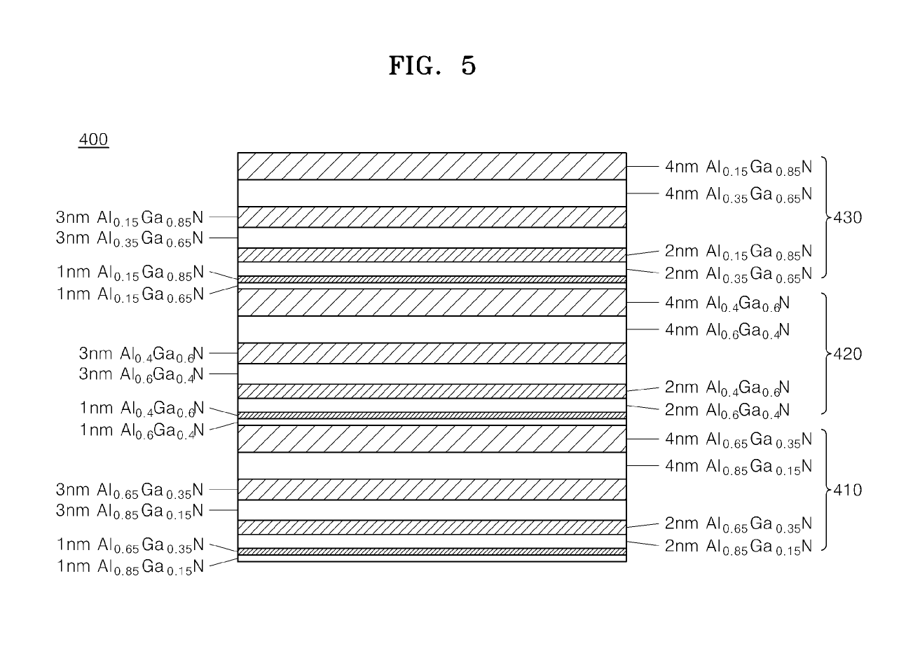

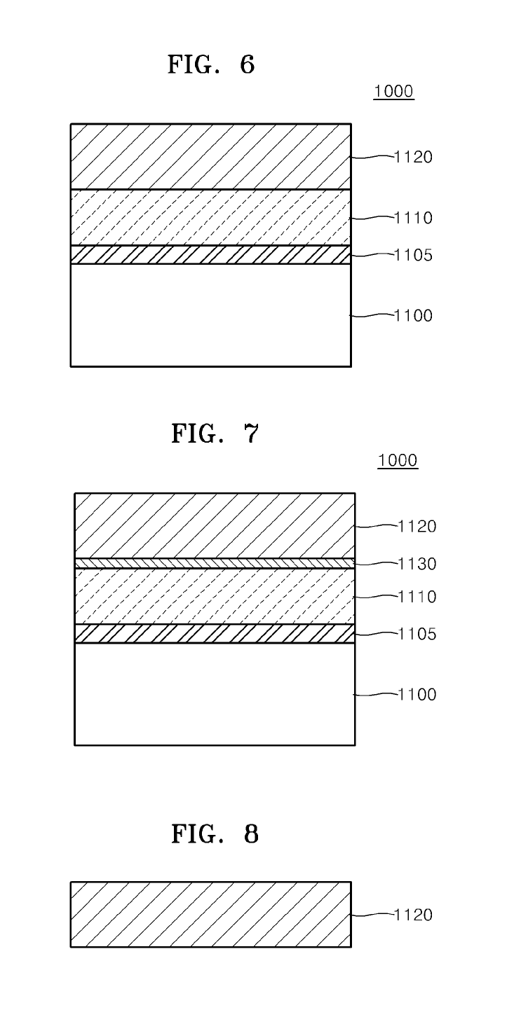

FIG. 6 is a schematic cross-sectional view of a semiconductor device according to yet further example embodiments.

In FIG. 6, a semiconductor device 1000 may include a substrate 1100, a superlattice structure 1110, and a nitride stack structure 1120. The substrate 1100 may be a silicon (Si)-based substrate containing Si, such as a Si substrate or a silicon carbide (SiC) substrate.

The superlattice structure 1110 may include a plurality of pairs of layers that are repeatedly stacked at least two times, and in this case, first and second layers constituting a pair are formed of different materials. A pair may be a minimum stack unit where thickness of layers vary. For example, the first layer may be formed of AlₓIn_{y}Ga_{1-x-y}N (0≦x, y≦1) and the second layer may be formed of AlₐIn_{b}Ga_{1-a-b}N (0≦a, b≦1 and x≠a). The first layer and the second layer may have different thicknesses and total thicknesses of pairs of layers may be different.

The superlattice structure 1110 may be, for example, one of the superlattice structures 10, 100, 200, 300, and 400 described with reference to FIGS. 1 through 5. A detailed description of a superlattice structure is not given here.

The nitride stack structure 1120 may include at least one nitride semiconductor layer. The at least one nitride semiconductor layer may be a layer to be grown on the substrate 1100 and may be formed of, for example, nitride containing Ga. The at least one nitride semiconductor layer may be formed of Alₓ₁In_{y1}Ga_{1-x1-y1}N (0≦x₁, y₁≦1, and x₁+y₁<1). For example, the at least one nitride semiconductor layer may be formed of a material including any one of GaN, InGaN, and AlInGaN. Alternatively, the at least one nitride semiconductor layer may be formed of nitride that does not contain Al. In addition, the at least one nitride semiconductor layer may be selectively doped, or undoped.

A seed growth layer 1105 may be disposed between the substrate 1100 and the superlattice structure 1110. The seed growth layer 1105 may be formed of Al_{c}In_{d}Ga_{1-c-a}N (0≦c, d≦1). The seed growth layer 1105 may be formed of, for example, AlN. The seed growth layer 1105 may prevent melt-back that occurs when the substrate 1100 and the nitride stack structure 1120 react with each other and may wet a superlattice structure to be grown or at least one nitride semiconductor layer. An Al source is initially injected during an initial stage of a growth process of the seed growth layer 1105 in order to prevent the substrate 1100 from being initially exposed to ammonia and being nitrified. For example, the seed growth layer 1105 may have a size of several tens to several hundreds of nanometers.

FIG. 7 is a schematic cross-sectional view of a semiconductor device according to still further example embodiments.

As shown in FIG. 7, at least one interlayer 1130 of a SiN interlayer and an AlGaN interlayer may be further interposed between the superlattice structure 1110 and the nitride stack structure 1120. Alternatively, at least one of a SiN interlayer and an AlGaN interlayer may be further inserted into a nitride semiconductor layer in the nitride stack structure 1120.

The superlattice structure 1110 may function as a buffer layer for reducing or preventing cracks due to a tensile stress generated by a thermal expansion difference when a nitride stack structure is grown on the substrate 1100. The substrate 1100, the seed growth layer 1105, and the superlattice structure 1110 may be removed during or after the manufacture of the semiconductor device 1000.

A semiconductor device according to example embodiments may reduce lattice dislocations and tensile stress when a nitride semiconductor layer is grown on a Si substrate or a SiC substrate. In addition, a large wafer may be manufactured by using a Si substrate or a SiC substrate. The semiconductor device may be used in a light-emitting diode, a Schottky diode, a laser diode, a field effect transistor, a power device, or the like.

A method of manufacturing a semiconductor device according to example embodiments will now be described with reference to FIGS. 6 and 7.

The superlattice structure 1110 and the nitride stack structure 1120 are stacked on the substrate 1100. The substrate 1100 may be a Si-based substrate containing Si, such as a Si substrate or a SiC substrate.

The superlattice structure 1110 may be, for example, one of the superlattice structures 10, 100, 200, 300, and 400 described with reference to FIGS. 1 through 5. A detailed description of a superlattice structure is not given here.

The nitride stack structure 1120 may include at least one nitride semiconductor layer. The at least one nitride semiconductor layer may be a layer to be grown on the substrate 1100 and may be formed of, for example, nitride containing Ga. The at least one nitride semiconductor layer may be formed of Alₓ₁In_{y1}Ga_{1-x1-y1}N (0≦x₁, y₁≦1, and x₁+y₁<1). For example, the at least one nitride semiconductor layer may be formed of a material including any one of GaN, InGaN, and AlInGaN. Alternatively, the at least one nitride semiconductor layer may be formed of nitride that does not contain Al. In addition, the at least one nitride semiconductor layer may be selectively doped, or undoped.

The seed growth layer 1105 may be disposed between the substrate 1100 and the superlattice structure 1110. As shown in FIG. 7, at least one interlayer 1130 of a SiN interlayer and an AlGaN interlayer may be further interposed between the superlattice structure 1110 and the nitride stack structure 1120. Alternatively, at least one of a SiN interlayer and an AlGaN interlayer may be further inserted into a nitride semiconductor layer in the nitride stack structure 1120.

Then, as shown in FIG. 8, the substrate 1100, the seed growth layer 1105, and the superlattice structure 1110 may be removed. Before the substrate 1100, the seed growth layer 1105, and the superlattice structure 1110 are removed, in order to support the nitride stack structure 1120, a supporting substrate may be further stacked on the nitride stack structure 1120. The nitride stack structure 1120 that remains after the substrate 1100, the seed growth layer 1105, and the superlattice structure 1110 are removed may include at least one nitride semiconductor layer. The at least one nitride semiconductor layer may be formed of, for example, nitride containing Ga. Also, the at least one nitride semiconductor layer may be selectively doped, or undoped.

The foregoing is illustrative of example embodiments and is not to be construed as limiting thereof. Although a few example embodiments have been described, those skilled in the art will readily appreciate that many modifications are possible in example embodiments without materially departing from the novel teachings. Accordingly, all such modifications are intended to be included within the scope of the disclosure as defined in the claims. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

What is claimed is:

1. A superlattice structure, comprising:
a plurality of pairs of layers in a pattern repeated at least two times,
wherein a first layer and a second layer of the plurality of pairs of layers constitute a pair,
the first layer is formed of AlₓIn_{y}Ga_{1-x-y}N (where 0≦x and y≦1),
the second layer is formed of AlₐIn_{b}Ga_{1-a-b}N (where 0≦a, b≦1 and x≠a), and
the first layer has a thickness equal to a thickness of the second layer, and
a total thickness of each of the plurality of pairs of layers is different than each other.

2. The superlattice structure of claim 1, wherein the total thickness of each of the plurality of pairs of layers increases in a direction in which the plurality of pairs of layers are stacked.

3. The superlattice structure of claim 2, wherein the total thickness of each of the plurality of pairs of layers increases linearly in the direction in which the plurality of pairs of layers are stacked.

4. The superlattice structure of claim 1, wherein a composition ratio of aluminum (Al) in the first layer is greater than a composition ratio of Al in the second layer, and
wherein a composition ratio of Al in each layer in the plurality of pairs of layers decreases, or an average composition ratio of Al in each of the plurality of pairs of layers decreases, in a direction in which the plurality of pairs of layers are stacked.

5. The superlattice structure of claim 4, wherein a composition ratio of Al in each layer of the plurality of pairs of layers decreases linearly, or an average composition ratio of Al in each of the plurality of pairs of layers decreases linearly, in the direction in which the plurality of pairs of layers are stacked.

6. The superlattice structure of claim 1, wherein a composition ratio of Al in the first layer is greater than a composition ratio of Al in the second layer, and
wherein the plurality of pairs of layers are repeatedly stacked having a same composition ratio of Al in a repeating pattern.

7. The superlattice structure of claim 2, wherein each of the first layer and the second layer has a thickness from about 0.1 nm to about 20 nm.

8. The superlattice structure of claim 2, wherein each of the first layer and the second layer has a thickness from about 0.1 nm to about 10 nm.

9. The superlattice structure of claim 2, wherein each of the plurality of pairs of layers further includes a third layer formed of AlₚIn_{q}Ga_{1-p-q}N (where 0≦p, q≦1 and x≠a≠p), and
wherein the third layer has a thickness equal to the thickness of the second layer.

10. The superlattice structure of claim 4 repeatedly stacked at least two times.

11. The superlattice structure of claim 10, wherein an average composition ratio of Al in the superlattice structure decreases in a direction in which the superlattice structure is repeatedly stacked.

12. A semiconductor device, comprising:
a seed growth layer on a substrate;
a superlattice structure on the seed growth layer; and
a nitride stack structure on the superlattice structure,
wherein the superlattice structure includes a plurality of pairs of layers in a pattern repeated at least two times, and
wherein a first layer and a second layer of the plurality of pairs of layers constitute a pair, the first layer is formed of AlₓIn_{y}Ga_{1-x-y}N (where 0≦x and y≦1) and the second layer is formed of AlₐIn_{b}Ga_{1-a-b}N (where 0≦a, b≦1 and x≠a),
the first layer has a thickness equal to a thickness of the second layer, and
a total thickness of each of the plurality of pairs of layers is different than each other.

13. The semiconductor device of claim 12, wherein a total thickness of each of the plurality of pairs of layers increases in a direction in which the plurality of pairs of layers are stacked.

14. The semiconductor device of claim 13, wherein the total thickness of each of the plurality of pairs of layers increases linearly in the direction in which the plurality of pairs of layers are stacked.

15. The semiconductor device of claim 12, wherein a composition ratio of aluminum (Al) in the first layer is greater than a composition ratio of Al in the second layer, and
wherein a composition ratio of Al in each layer in the plurality of pairs of layers decreases, or an average composition ratio of Al in each of the plurality of pairs of layers decreases, in a direction in which the plurality of pairs of layers are stacked.

16. The semiconductor device of claim 15, wherein a composition ratio of Al in each layer of the plurality of pairs of layers decreases linearly, or an average composition ratio of Al in each of the plurality of pairs of layers decreases linearly, in a direction in which the plurality of pairs of layers are stacked.

17. The semiconductor device of claim 12, wherein a composition ratio of Al in the first layer is greater than a composition ratio of Al in the second layer, and
wherein the plurality of pairs of layers are repeatedly stacked having a same composition ratio of Al in a repeating pattern.

18. The semiconductor device of claim 13, wherein each of the first layer and the second layer has a thickness from about 0.1 nm to about 20 nm.

19. The semiconductor device of claim 13, wherein each of the first layer and the second layer has a thickness from about 0.1 nm to about 10 nm.

20. The semiconductor device of claim 13, wherein each of the plurality of pairs of layers further includes a third layer formed of AlₚIn_{q}Ga_{1-p-q}N (where 0≦p, q≦1 and x≠a≠p), and
wherein the third layer has a thickness equal to the thickness of the second layer.

21. The semiconductor device of claim 15, wherein the superlattice structure is repeatedly stacked at least two times.

22. The semiconductor device of claim 21, wherein an average composition ratio of Al in the superlattice structure decreases in a direction in which the superlattice structure is repeatedly stacked.

23. The semiconductor device of claim 12, wherein the substrate contains silicon (Si).

24. The semiconductor device of claim 12, wherein the seed growth layer is formed of Al_{c}In_{d}Ga_{1-c-d}N (wherein 0≦c, d≦1).

25. The semiconductor device of claim 12, further comprising:
at least one nitride interlayer selected from a SiN interlayer and an AlGaN interlayer in a nitride semiconductor layer in the nitride stack or over the superlattice structure.

26. A superlattice structure, comprising:
a plurality of pairs of layers in a pattern repeated at least two times,
wherein a first layer and a second layer of the plurality of pairs of layers constitute a first pair, and a third layer and a fourth layer of the plurality of pairs of layers constitute a second pair,
either a composition ratio of aluminum (Al) in the first layer is greater than a composition ratio of Al in the second layer or a composition ratio of Al in the first pair is greater than a composition ratio of Al in the second pair,
the first layer has a thickness equal to a thickness of the second layer, and the third layer has a thickness equal to a thickness of the fourth layer, and
a total thickness of each of the plurality of pairs of layers is different than each other.

27. The superlattice structure of claim 26, wherein the second layer is over the first layer, and the fourth layer is over the third layer, and
the second pair is over the first pair.

28. The superlattice structure of claim 26, wherein a total thickness of the first pair is less than a total thickness of the second pair.

29. A method of manufacturing a semiconductor device, comprising:
stacking on a substrate a first layer formed on AlₓIn_{y}Ga_{1-x-y}N (where 0≦x and y≦1);
stacking on the first layer a second layer formed of AlₐIn_{b}Ga_{1-a-b}N (where 0≦a, b≦1 and x≠a);
alternately stacking the first layer and the second layer on the second layer at least one time; and
stacking a nitride stack structure on the stacked layer,
wherein a plurality of pairs of layers each pair including the first layer and the second layer are stacked,
the first layer has a thickness equal to a thickness of the second layer, and
a total thickness of each of the plurality of pairs of layers is different than each other.

30. The method of claim 29, wherein a total thickness of each of the plurality of pairs of layers increases in a direction in which the plurality of pairs of layers are stacked.

31. The method of claim 29, wherein the total thickness of each of the plurality of pairs of layers increases linearly in a direction in which the plurality of pairs of layers are stacked.

32. The method of claim 29, wherein a composition ratio of aluminum (Al) in the first layer is greater than a composition ratio of Al in the second layer, and
wherein a composition ratio of Al in each layer in the plurality of pairs of layers decreases, or an average composition ratio of Al in each of the plurality of pairs of layers decreases, in a direction in which the plurality of pairs of layers are stacked.

33. The method of claim 29, further comprising removing the substrate and the plurality of pairs of layers each pair including the first layer and the second layer.
